(19) United States
(12) Patent Application Publication
(10) Pub. No.: US 2024/0414893 A1
(43) Pub. Date: Dec. 12, 2024

(54) SYSTEMS AND METHODS FOR PROVIDING THERMAL PROTECTION FOR STEERING SYSTEMS

(71) Applicant: Steering Solutions IP Holding Corporation, Saginaw, MI (US)

(72) Inventors: RUIYANG HE, JIANGSU (CN); YEJUN TANG, JIANGSU (CN); CLARK TU, JIANGSU (CN); QIANGDA YANG, JIANGSU (CN); PENGXIANG YANG, JIANGSU (CN); PENGCHENG WANG, JIANGSU (CN)

(21) Appl. No.: 18/460,009

(22) Filed: Sep. 1, 2023

(30) Foreign Application Priority Data
Jun. 9, 2023 (CN) 2023106870746

(51) Int. Cl. H05K 7/20

(52) U.S. Cl. CPC H05K 7/20845

(57) ABSTRACT

A method for electrical component temperature control includes, in response to an ignition on signal indicating an ignition is in an on position, receiving a plurality of temperature values from a temperature sensor over a period, the temperature sensor being associated with at least one electrical component; determining a slope of a change in temperature over the period based on the plurality of temperature values; in response to an absolute value of the slope being less than or equal to a threshold, initiating a first cooling function; and, in response to the absolute value of the slope being greater than the threshold, initiating a second cooling function.

### CROSS-REFERENCES TO RELATED APPLICATIONS

This patent application claims priority to Chinese Patent Application No. 2023106870746, filed Jun. 9, 2023 which is incorporated herein by reference in its entirety.

### TECHNICAL FIELD

This disclosure relates to steering systems and in particular to systems and methods for providing thermal protection for steering systems.

### BACKGROUND

A vehicle, such as a car, truck, sport utility vehicle, crossover, mini-van, marine craft, aircraft, all-terrain vehicle, recreational vehicle, or other suitable forms of transportation, typically includes a steering system, such as an electronic power steering (EPS) system, a steer-by-wire (SbW) steering system, a hydraulic steering system, or other suitable steering system. The steering system of such a vehicle typically controls various aspects of vehicle steering including providing steering assist to an operator of the vehicle, controlling steerable wheels of the vehicle, and the like.

Such steering systems include various electrical components, such as circuits (e.g., comprising inductors, capacitors, resistors, metal-oxide-semiconductor field-effect transistors (MOSFETs), and the like), motors, sensors, and/or other suitable electrical components. Such electrical components may be subject to damage or wear due to temperature increases resulting from operation of such steering systems.

### SUMMARY

This disclosure relates generally to vehicle steering systems.

An aspect of the disclosed embodiments includes a method for electrical component temperature control. The method includes, in response to an ignition on signal indicating an ignition is in an on position, receiving a plurality of temperature values from a temperature sensor over a period, the temperature sensor being associated with at least one electrical component; determining a slope of a change in temperature over the period based on the plurality of temperature values; in response to an absolute value of the slope being less than or equal to a threshold, initiating a first cooling function; and, in response to the absolute value of the slope being greater than the threshold, initiating a second cooling function.

Another aspect of the disclosed embodiments includes a system for electrical component temperature control. The system includes a processor, and a memory. The memory includes instructions that, when executed by the processor, cause the processor to: in response to an ignition on signal indicating an ignition is in an on position, receive a plurality of temperature values from a temperature sensor over a period, the temperature sensor being associated with at least one electrical component; determine a slope of a change in temperature over the period based on the plurality of temperature values; in response to an absolute value of the slope being less than or equal to a threshold, initiate a first cooling function; and, in response to the absolute value of the slope being greater than the threshold, initiate a second cooling function.

Another aspect of the disclosed embodiments includes an apparatus for electrical component temperature control. The apparatus includes a controller configured to: in response to an ignition on signal indicating an ignition is in an on position, receive a plurality of temperature values from a temperature sensor over a period that starts at an ignition off signal indicating the ignition is off and ends a predetermined time after the ignition on signal indicates that the ignition is on, the temperature sensor being associated with at least one electrical component; determine a slope of a change in temperature over the period based on the plurality of temperature values; in response to an absolute value of the slope being less than or equal to a threshold, initiate a first cooling function configured to cool the at least one electrical component based on a first cooling rate; and, in response to the absolute value of the slope being greater than the threshold, initiate a second cooling function configured to cool the at least one electrical component based on a second cooling rate.

These and other aspects of the present disclosure are disclosed in the following detailed description of the embodiments, the appended claims, and the accompanying figures.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 generally illustrates a vehicle according to the principles of the present disclosure.

FIG. 2 generally illustrates a controller according to the principles of the present disclosure.

FIGS. 3A and 3B generally illustrate vehicle characteristics over a period according to the principles of the present disclosure.

FIG. 4 is a flow diagram generally illustrating a thermal protection method according to the principles of the present disclosure.

FIG. 5A generally illustrates a printed circuit board having an electrical component and a sensor according to the principles of the present disclosure.

FIG. 5B is a chart generally illustrating temperature of an objected lumped model versus clock cycles.

FIG. 5C genera is a chart generally illustrating slope of change of the temperature in FIG. 5B.

FIG. 6 generally illustrates a lookup table corresponding torque limitations of a steering system to slope change in temperature, according to the principles of the present disclosure.

FIG. 7 is a flow diagram generally illustrating an alternative thermal protection method according to the principles of the present disclosure.

FIG. 8 generally illustrates a sequence model to estimate the ignition off-on time according to the principles of the present disclosure.

FIG. 9 is a flow diagram generally illustrating an alternative thermal protection method according to the principles of the present disclosure.

FIG. 10 is a flow diagram generally illustrating an alternative thermal protection method according to the principles of the present disclosure.

### DETAILED DESCRIPTION

The following discussion is directed to various embodiments of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

As described, a vehicle, such as a car, truck, sport utility vehicle, crossover, mini-van, marine craft, aircraft, all-terrain vehicle, recreational vehicle, or other suitable forms of transportation, typically includes a steering system, such as an EPS system, an SbW steering system, a hydraulic steering system, or other suitable steering system. The steering system of such a vehicle typically controls various aspects of vehicle steering including providing steering assist to an operator of the vehicle, controlling steerable wheels of the vehicle, and the like.

Such steering systems include various electrical components, such as circuits (e.g., comprising inductors, capacitors, resistors, MOSFETs, and the like), motors, sensors, and/or other suitable electrical components. Such electrical components may be subject to damage or wear due to temperature increases resulting from operation of such steering systems. To avoid or reduce such damage or wear, thermal protect data (e.g., received from one or more thermal sensors) may be used trigger various thermal control techniques (e.g., such as cooling to reduce or control component temperature).

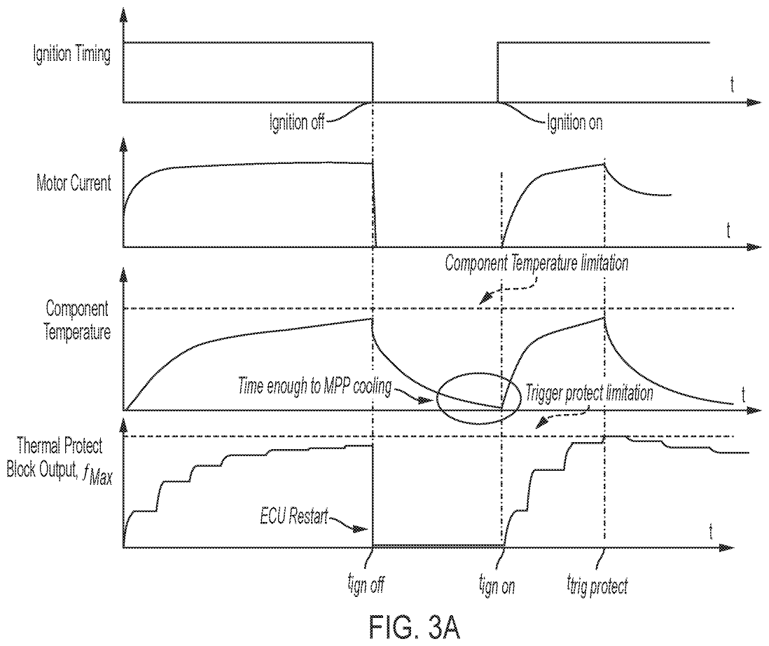

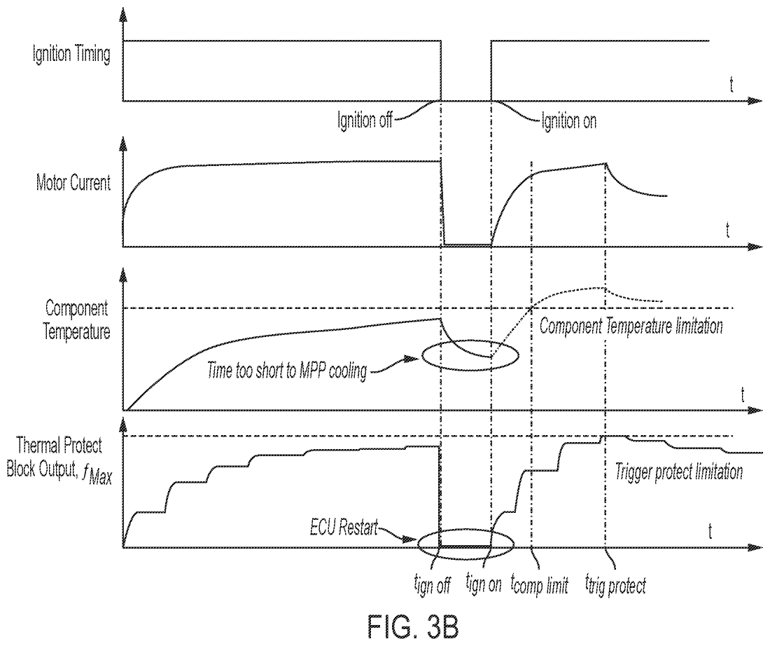

Typically, once an ignition of a vehicle is off, the thermal protect data of a steering system of the vehicle resets (e.g., because the clock of an associated controller of the steering system is lost when the ignition is powered off). Then the EPS is defaulted starting from the cooling. In general, the time between ignition off and ignition on is sufficient for components of the steering system to cool. As is generally illustrated in FIG. 3A, when there is enough time between ignition off and ignition on for the components of the steering system to cool, the while the ignition is on, the controller receives thermal protect data and adjusts a thermal protect model based on a current temperature of one or more of the components of the steering system. The thermal protect model may calculate or recalculate a temperature value of one or more components of the steering system and apply thermal protection, according.

However, as is generally illustrated in FIG. 3B, if the period between ignition of and ignition on (e.g., for frequent power-on and power off), the components (e.g., such as the MOSFETs, motor, capacitors, and/or other suitable components) of the steering system may not have enough time to cool. In this situation, the controller, which has lost temperature data from before the ignition is on, may start with the assumption that the components have cooled. As such, proceeding as described with respect to FIG. 3A, may be suboptimal and/or may lead to thermal damage or wear of the components of the steering system.

Accordingly, systems and methods, such as those described herein, configured to provide improved thermal protection for steering systems, may be desirable. In some embodiments, the systems and methods described herein may be configured to identify a steering system thermal statement at ignition on and determine, based on the thermal statement, whether the steering system has cooled below a threshold (e.g., which may include a threshold period, a threshold temperature, and/or other suitable threshold) or has not cooled below the threshold.

In some embodiments, the systems and methods described herein may be configured to judge s thermal state of the steering system before ignition by using the slope of the temperature change curve of the temperature sensor. The systems and methods described herein may be configured to provide a mathematical model of a thermal module, based on the relationship between the slope and temperature of thermal statement.

In some embodiments, the systems and methods described herein may be configured to, in response to an ignition on signal indicating an ignition is in an on position, receive a plurality of temperature values from a temperature sensor over a period. The temperature sensor may be associated with at least one electrical component. The at least one electrical component is associated with a steering system of a vehicle, such as an EPS steering system, a SbW steering system, a hydraulic steering system, and/or the like. The period may include a period that starts at the ignition on signal indicating that the ignition is on and ends at a predetermined time, a period that starts at an ignition off signal indicating the ignition is off and ends a predetermined time after the ignition on signal indicates that the ignition is on, and/or any other suitable period.

In some embodiments, the systems and methods described herein may be configured to determine a time associated with the ignition off signal and a time associated with the ignition on signal. The systems and methods described herein may be configured to estimate an ignition off period associated based on the time associated with the ignition off signal and the tie associated with the ignition on signal.

In some embodiments, the systems and methods described herein may be configured to determine a slope of a change in temperature over the period based on the plurality of temperature values. For example, the systems and methods described herein may be configured to determine a first temperature value associated with the at least one electrical component at the time associated with the ignition off signal. The systems and methods described herein may be configured to determine a second temperature value associated with the at least one electrical component at the time associated with the ignition on signal. The systems and methods described herein may be configured to determine a slope of change in temperature over the ignition off period based on the estimated ignition off period, the first temperature value, and the second temperature value. The systems and methods described herein may be configured to determine the slope of the change in temperature over the period based on the plurality of temperature values and the slope of change in temperature over the ignition off period.

The systems and methods described herein may be configured to, in response to an absolute value of the slope being less than or equal to a threshold, initiate a first cooling function. The first cooling function may be configured to cool the at least one electrical component based on a first cooling rate. The systems and methods described herein may be configured to, in response to the absolute value of the slope being greater than the threshold, initiate a second cooling function. The second cooling function may be configured to cool the at least one electrical component based on a second cooling rate.

In some embodiments, the systems and methods described herein may be configured to estimate the time between ignition off and on based on the thermal time constant of an existing components, and/or a temperature sensor.

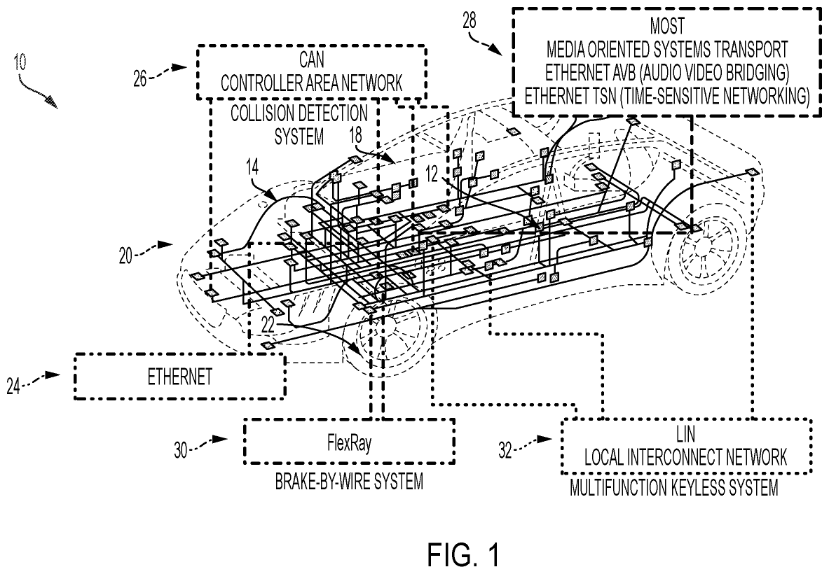

FIG. 1 generally illustrates a vehicle 10 according to the principles of the present disclosure. The vehicle 10 may include any suitable vehicle, such as a car, a truck, a sport utility vehicle, a mini-van, a crossover, any other passenger vehicle, any suitable commercial vehicle, or any other suitable vehicle. While the vehicle 10 is illustrated as a passenger vehicle having wheels and for use on roads, the principles of the present disclosure may apply to other vehicles, such as planes, boats, trains, drones, or other suitable vehicles

The vehicle 10 includes a vehicle body 12 and a hood 14. A passenger compartment 18 is at least partially defined by the vehicle body 12. Another portion of the vehicle body 12 defines an engine compartment 20. The hood 14 may be moveably attached to a portion of the vehicle body 12, such that the hood 14 provides access to the engine compartment 20 when the hood 14 is in a first or open position and the hood 14 covers the engine compartment 20 when the hood 14 is in a second or closed position. In some embodiments, the engine compartment 20 may be disposed on rearward portion of the vehicle 10 than is generally illustrated.

The passenger compartment 18 may be disposed rearward of the engine compartment 20, but may be disposed forward of the engine compartment 20 in embodiments where the engine compartment 20 is disposed on the rearward portion of the vehicle 10. The vehicle 10 may include any suitable propulsion system including an internal combustion engine, one or more electric motors (e.g., an electric vehicle), one or more fuel cells, a hybrid (e.g., a hybrid vehicle) propulsion system comprising a combination of an internal combustion engine, one or more electric motors, and/or any other suitable propulsion system.

In some embodiments, the vehicle 10 may include a petrol or gasoline fuel engine, such as a spark ignition engine. In some embodiments, the vehicle 10 may include a diesel fuel engine, such as a compression ignition engine. The engine compartment 20 houses and/or encloses at least some components of the propulsion system of the vehicle 10. Additionally, or alternatively, propulsion controls, such as an accelerator actuator (e.g., an accelerator pedal), a brake actuator (e.g., a brake pedal), a handwheel, and other such components are disposed in the passenger compartment 18 of the vehicle 10. The propulsion controls may be actuated or controlled by an operator of the vehicle 10 and may be directly connected to corresponding components of the propulsion system, such as a throttle, a brake, a vehicle axle, a vehicle transmission, and the like, respectively. In some embodiments, the propulsion controls may communicate signals to a vehicle computer (e.g., drive by wire) which in turn may control the corresponding propulsion component of the propulsion system. As such, in some embodiments, the vehicle 10 may be an autonomous vehicle.

In some embodiments, the vehicle 10 includes a transmission in communication with a crankshaft via a flywheel or clutch or fluid coupling. In some embodiments, the transmission includes a manual transmission. In some embodiments, the transmission includes an automatic transmission. The vehicle 10 may include one or more pistons, in the case of an internal combustion engine or a hybrid vehicle, which cooperatively operate with the crankshaft to generate force, which is translated through the transmission to one or more axles, which turns wheels 22. When the vehicle 10 includes one or more electric motors, a vehicle battery, and/or fuel cell provides energy to the electric motors to turn the wheels 22.

The vehicle 10 may include automatic vehicle propulsion systems, such as a cruise control, an adaptive cruise control, automatic braking control, other automatic vehicle propulsion systems, or a combination thereof. The vehicle 10 may be an autonomous or semi-autonomous vehicle, or other suitable type of vehicle. The vehicle 10 may include additional or fewer features than those generally illustrated and/or disclosed herein.

In some embodiments, the vehicle 10 may include an Ethernet component 24, a controller area network (CAN) bus 26, a media oriented systems transport component (MOST) 28, a FlexRay component 30 (e.g., brake-by-wire system, and the like), and a local interconnect network component (LIN) 32. The vehicle 10 may use the CAN bus 26, the MOST 28, the FlexRay Component 30, the LIN 32, other suitable networks or communication systems, or a combination thereof to communicate various information from, for example, sensors within or external to the vehicle, to, for example, various processors or controllers within or external to the vehicle. The vehicle 10 may include additional or fewer features than those generally illustrated and/or disclosed herein.

In some embodiments, the vehicle 10 may include a steering system, such as an EPS system, a steering-by-wire steering system (e.g., which may include or communicate with one or more controllers that control components of the steering system without the use of mechanical connection between the handwheel and wheels 22 of the vehicle 10), a hydraulic steering system (e.g., which may include a magnetic actuator incorporated into a valve assembly of the hydraulic steering system), or other suitable steering system.

The steering system may include an open-loop feedback control system or mechanism, a closed-loop feedback control system or mechanism, or combination thereof. The steering system may be configured to receive various inputs, including, but not limited to, a handwheel position, an input torque, one or more roadwheel positions, other suitable inputs or information, or a combination thereof.

Additionally, or alternatively, the inputs may include a handwheel torque, a handwheel angle, a motor velocity, a vehicle speed, an estimated motor torque command, other suitable input, or a combination thereof. The steering system may be configured to provide steering function and/or control to the vehicle 10. For example, the steering system may generate an assist torque based on the various inputs. The steering system may be configured to selectively control a motor of the steering system using the assist torque to provide steering assist to the operator of the vehicle 10.

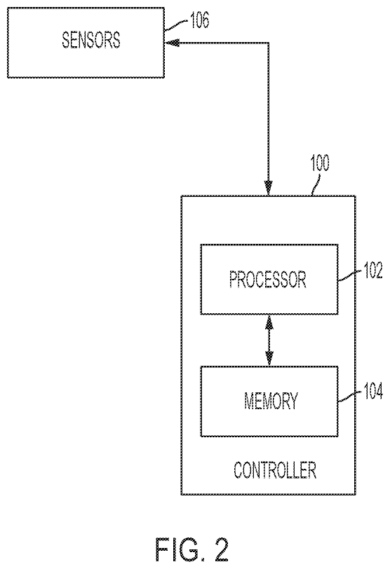

In some embodiments, the vehicle 10 may include a controller, such as controller 100, as is generally illustrated in FIG. 2. The controller 100 may include any suitable controller, such as an electronic control unit or other suitable controller. The controller 100 may be configured to control, for example, the various functions of the steering system and/or various functions of the vehicle 10. The controller 100 may include a processor 102 and a memory 104. The processor 102 may include any suitable processor, such as those described herein. Additionally, or alternatively, the controller 100 may include any suitable number of processors, in addition to or other than the processor 102. The memory 104 may comprise a single disk or a plurality of disks (e.g., hard drives), and includes a storage management module that manages one or more partitions within the memory 104. In some embodiments, memory 104 may include flash memory, semiconductor (solid state) memory or the like. The memory 104 may include Random Access Memory (RAM), a Read-Only Memory (ROM), or a combination thereof. The memory 104 may include instructions that, when executed by the processor 102, cause the processor 102 to, at least, control various aspects of the vehicle 10. Additionally, or alternatively, the memory 104 may include instructions that, when executed by the processor 102, cause the processor 102 to, at least, control various functions of the steering system and/or perform any other suitable function, including those of the systems and methods described herein.

The controller 100 may receive one or more signals from various measurement devices or sensors 106 indicating sensed or measured characteristics of the vehicle 10. The sensors 106 may include any suitable sensors, measurement devices, and/or other suitable mechanisms. For example, the sensors 106 may include one or more torque sensors or devices, one or more handwheel position sensors or devices, one or more motor position sensor or devices, one or more position sensors or devices, one or more temperature sensors or devices, other suitable sensors or devices, or a combination thereof. The one or more signals may indicate a handwheel torque, a handwheel angle, a motor velocity, a vehicle speed, temperature, other suitable information, or a combination thereof.

In some embodiments, the controller 100 may be configured to provide thermal protection for the components of the vehicle 10, including, but not limited to, various electrical and/or mechanical components of the steering system of the vehicle 10. For example, the controller 100 may, in response to an ignition on signal indicating an ignition of the vehicle 10 is in an on position, receive a plurality of temperature values from a temperature sensor, such as the sensor 106, over a period. The sensor 106 may be associated with at least one component, such as at least one electrical component or at least one mechanical component, of the steering system of the vehicle 10. The sensor 106 may be configured to sense or measure a temperature (e.g., ambient or other suitable temperature) of the at least one component of the steering system or the vacuole 10. The period may include a period that starts at the ignition on signal indicating that the ignition is on and ends at a predetermined time, a period that starts at an ignition off signal indicating the ignition is off and ends a predetermined time after the ignition on signal indicates that the ignition is on, and/or any other suitable period.

In some embodiments, the controller 100 may determine a time associated with the ignition off signal and a time associated with the ignition on signal. The controller 100 may estimate an ignition off period associated based on the time associated with the ignition off signal and the tie associated with the ignition on signal.

In some embodiments, the controller 100 may determine a slope of a change in temperature over the period based on the plurality of temperature values. For example, the controller 100 may determine a first temperature value associated with the at least one component at the time associated with the ignition off signal. The controller 100 may determine a second temperature value associated with the at least one component at the time associated with the ignition on signal. The controller 100 may determine a slope of change in temperature over the ignition off period based on the estimated ignition off period, the first temperature value, and the second temperature value. The controller 100 may determine the slope of the change in temperature over the period based on the plurality of temperature values and the slope of change in temperature over the ignition off period.

The controller 100 may, in response to an absolute value of the slope being less than or equal to a threshold, initiate a first cooling function. The first cooling function may be configured to cool the at least one component based on a first cooling rate. The controller 100 may, in response to the absolute value of the slope being greater than the threshold, initiate a second cooling function. The second cooling function may be configured to cool the at least one electrical component based on a second cooling rate.

In some embodiments, the controller 100 may perform the methods described herein. However, the methods described herein as performed by the controller 100 are not meant to be limiting, and any type of software executed on a controller or processor can perform the methods described herein without departing from the scope of this disclosure. For example, a controller, such as a processor executing software within a computing device, can perform the methods described herein.

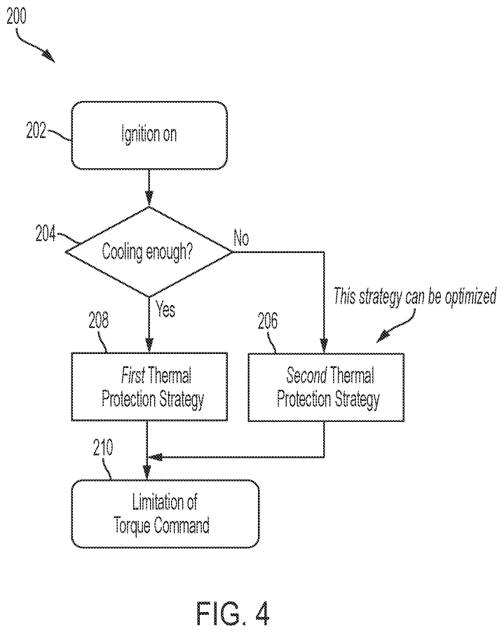

FIG. 4 is a flow diagram generally illustrating a thermal protection method 200 according to the principles of the present disclosure. At 202, the method 200 receives an ignition on signal. For example, the controller 100 may receive the ignition on signal indicating that the ignition of the vehicle 10 is on.

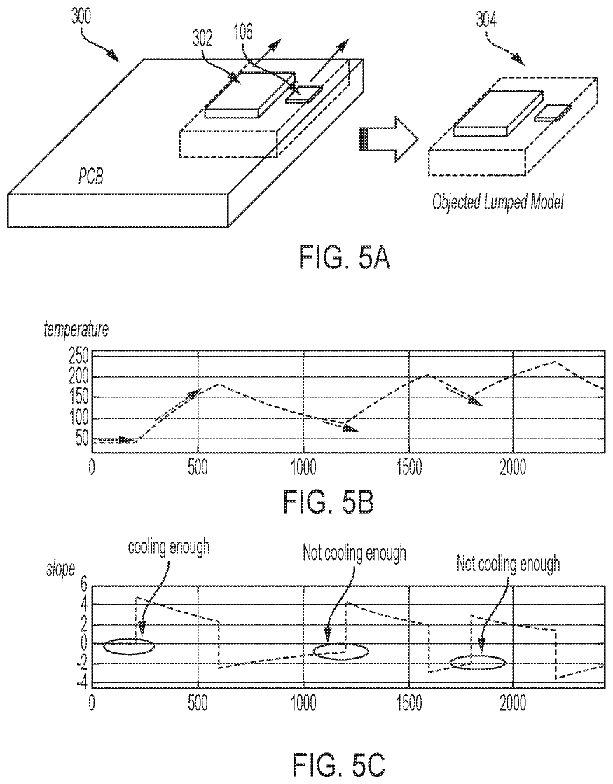

At 204, the method 200 determines whether components of the steering system of the vehicle 10 are cooling enough. For example, the controller 100 may determine whether the components of the steering system of the vehicle 10 have cooled for a threshold period, below a threshold temperature, and/or any other suitable threshold. For example, as is generally illustrated in FIGS. 5A and 5B, the controller 100 may determine or receive temperature data comprising a plurality of temperature values over a period from an objected lumped model 304 that comprises at least one electrical component 302 of the steering system and a sensor 106. The electrical component 302 and the sensor 106 may be disposed on a printed circuit board (PCB) 300.

The controller 100 may calculate a slope value for the temperature data (e.g., by determining a rate of change of the plurality of temperature values of the temperature data). FIG. 5B generally illustrates temperature (vertical axis) of the objected lumped model 304 versus the controller 100 clock cycles (horizontal axis) and FIG. 5C generally illustrates slope (vertical axis) versus the controller 100 clock cycles. As is illustrated, when the slope value is at or near 0, the controller 100 determines that the objected lumped model 304 is cooling enough and when the slope value is negative (e.g., less than 0), the controller 100 determines that the objected lumped model 304 is not cooling enough.

The mathematical expression of thermal characteristic for objected lumped model 304 may be described as equation (1):

$$\{ \begin{matrix}ρ cV \frac{dt}{d τ} = - h ( t - t ∞ ) \\ θ = t - {t}_{∞}\end{matrix}$$

Equation (1) can be rewritten as:

$$ρ cV \frac{d θ}{d τ} = - h θ \qquad ( 2 )$$

With an initial condition of:

θ(0)=t₀−t_{∞}=θ₀ (3)

θ(t) can be solved for according to:

$$θ = {θ}_{0} exp ( - \frac{hA}{ρ cV} τ ) \qquad ( 4 )$$

$${τ}_{e} = \frac{ρ cV}{hAs} \qquad ( 5 )$$

The slope can be expressed exponentially as:

$$\frac{d θ}{d τ} = - \frac{1}{{τ}_{e}} {θ}_{0} exp ( - \frac{1}{{τ}_{e}} τ ) \qquad ( 6 )$$

If the controller 100 determines that the components of the steering system have not cooled enough, the method 200 continues at 206. Alternatively, if the controller 100 determines that the components of the steering system have cooled enough, the method 200 continues at 208.

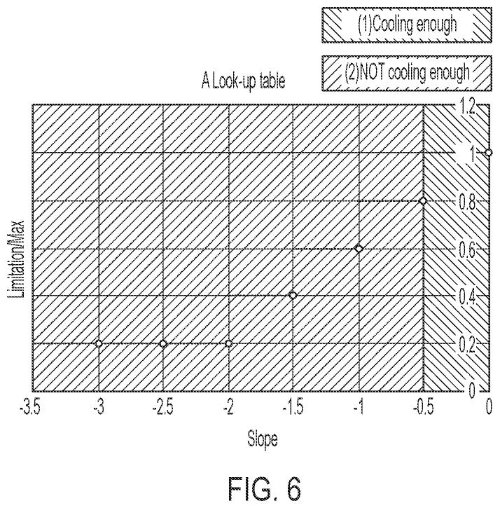

At 208, the method 200 executes a first thermal protection strategy. For example, the controller 100 may cool the objected lumped model 304 based on a first cooling rate. The first cooling rate may be a predefined rate configured to cool the temperature of the objected lumped model 304. In some embodiments, a red-line filter (e.g., protection limitation) of the steering system may be 1, when cooling the objected lumped model 304 using the first cooling rate. FIG. 6 generally illustrates a lookup table illustrating protection limitation (vertical axis) versus a slope (horizontal axis).

At 210, the method 200 determines a limitation of a torque command of the steering system, based on the first thermal protection strategy. For example, the controller 100 may determine the limitation of the torque command of the steering system, based on the first thermal protection strategy.

At 206, the method 200 executes a second thermal protection strategy. For example, the controller 100 may cool the objected lumped model 304 based on a second cooling rate. The second cooling rate may be determined by reducing the red-line filter based on the slope, as is illustrated in FIG. 6.

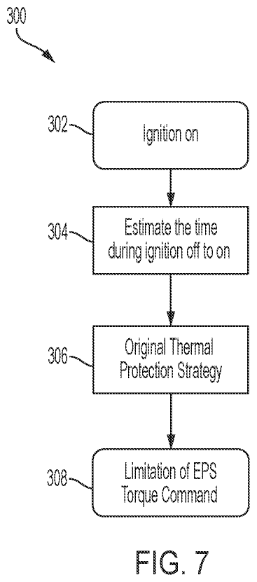

FIG. 7 is a flow diagram generally illustrating an alternative thermal protection method 300 according to the principles of the present disclosure. At 302, the method 300 receives an ignition on signal. For example, the controller 100 may receive the ignition on signal indicating that the ignition of the vehicle 10 is on.

At 304, the method 300 estimates a period between the ignition being off and the ignition being on. As described, during frequent ignition off/ignition on cycles, the steering system of the vehicle 10 may not cool during the period that the ignition is off. Accordingly, the controller 100 may estimate the period between the ignition being off and the ignition being on and may use the estimate to adjust the thermal protection of the steering system of the vehicle 10. For example, the controller 100 may record a temperature associated with the objected lumped model 304 at some time prior to ignition off (e.g., the controller 100 may periodically record the temperature of the objected lumped model 304). The controller 100 may record a temperature of the objected lumped model 304 after receiving an ignition on signal. The controller 100 may estimate the period between ignition off and ignition on based on the recorded temperatures.

The controller 100 may use the estimated period to provide thermal protection to the objected lumped model 304. For example, the controller 100 may calculate a thermal protect nominal value, which may make the thermal management strategy relatively reliable. In some embodiments, the controller 100 may record at least three temperature values of the objected lumped model 304: (1) Ta: Ambient temperature (e.g., when the ignition is on again and the steering system is is cooling enough, which need be recorded into the EEROM); (2) Teo: Temperature at ignition off (e.g., the data monitored by the sensor 106 is been updated in real time—as ignition off, the temperature data is stored into the EEROM); and (3) Te: Temperature at ignition on again (which may include a constant depended on the thermal properties of the objected lumped model 304). The estimated temperature may be defined according to: t=−τeln(Te−Ta/Teo−Ta).

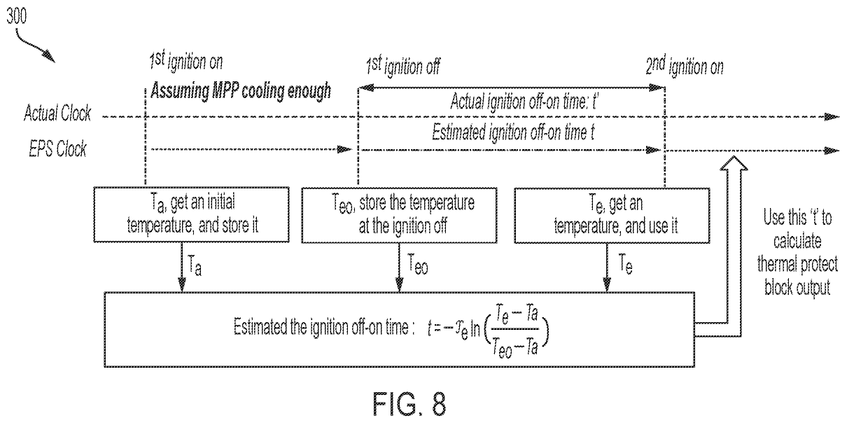

FIG. 8 generally illustrates a sequence model to estimate the ignition off-on time. Shown as a sequence diagram, FIG. 8 demonstrates the progress of estimating the ignition off-on time based on the temperature of the objected lumped model 304.

The mathematical description of the temperature of the objected lumped model 304 may be defined according to:

$$ρ cV \frac{dT}{dt} = hAs ( Te - Ta )$$

$$Te = Ta + ( Teo - Ta ) exp ( - t \frac{hAs}{ρ cV} )$$

$$t = - τ e ln ( \frac{Te - Ta}{Teo - Ta} )$$

$${τ}_{e} = \frac{ρ cV}{hAs}$$

Where, Tₑₒ is the temperature at ignition off, Ta is the ambient temperature, and Te is the temperature at ignition on again, as described.

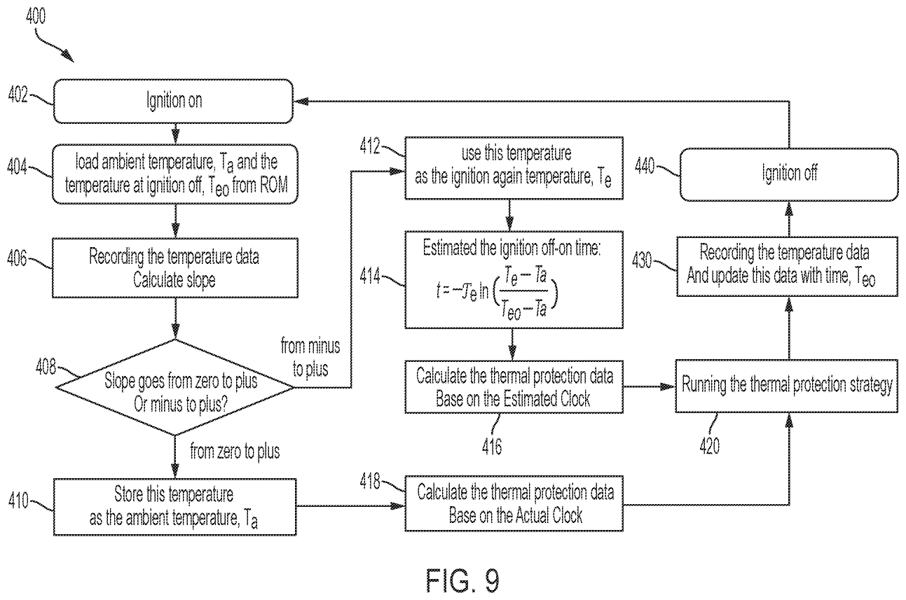

FIG. 9 is a flow diagram generally illustrating an alternative thermal protection method 400 according to the principles of the present disclosure. At 402, the method 400 receives an ignition on signal. For example, the controller 100 may receive the ignition on signal indicating that the ignition of the vehicle 10 is on.

At 404, the method 400 loads an ambient temperature and the temperature at ignition off from memory. For example, the controller 100 retrieves the ambient temperature and the temperature at ignition off of the objected lumped model 304 from the memory 104.

At 406, the method 400 records the temperature data and calculates the slope. For example, the controller 100 records the temperature data and calculates the slope value.

At 408, the method 400 determines whether the slope changes from zero to greater than zero of from less than zero to greater than zero. For example, controller 100 may determine whether the slope changes from zero to greater than zero of from less than zero to greater than zero. If the controller 100 determines that the slope changes from zero to greater than zero, the method 400 continues at 410. Alternatively, if the controller 100 determines that the slope changes from less than zero to greater than zero, the method 400 continues at 412.

At 410, the method 400 stores the temperature as the ambient temperature. For example, the controller 10 may store the temperature as the ambient temperature.

At 418, the method 400 calculates the thermal protection data based on an actual clock. For example, the controller 100 may calculate the thermal protection data based on the actual clock.

At 420, the method 400 runs the thermal protection strategy. For example, the controller 100 may cool the steering system of the vehicle 10 based on the first thermal protection function.

At 430, the method 400 records the temperature data and updates the data with time. For example, the controller 100 periodically records the temperature data.

At 440, the method 400 receives a signal indicating that the ignition is off. For example, the controller 100 may receive a signal indicating that the ignition is off.

At 412, the method 400 uses the temperature as the ignition on again temperature. For example, the controller 100 may use the temperature as the temperature at ignition on.

At 414, the method 400 estimates the ignition off-on time. For example, the controller 100 may estimate the period between the ignition being off and the ignition being on.

At 416, the method 400 calculates the thermal protection data based on the estimated clock. For example, the controller 100 may calculate the thermal protection data based on the estimated period between the ignition being off and the ignition being on.

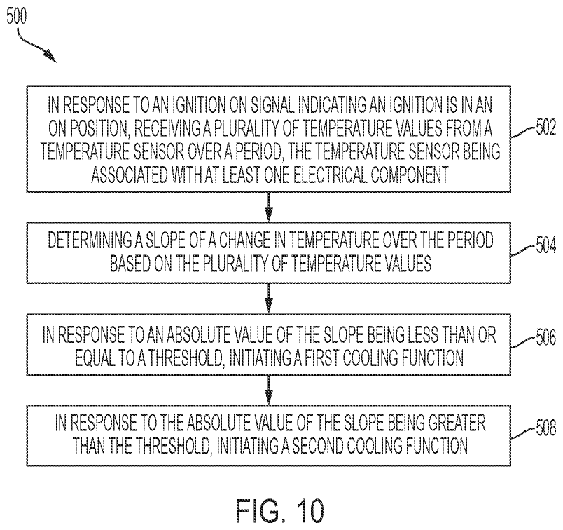

FIG. 10 is a flow diagram generally illustrating an alternative thermal protection method 500, according to the principles of the present disclosure. At 502, the method 500, in response to an ignition on signal indicating an ignition is in an on position, receives a plurality of temperature values from a temperature sensor over a period. For example, the controller 100 may receive the plurality of temperature values from the temperature sensor 106 over the period. The temperature sensor may be associated with at least one electrical component.

At 504, the method 500 determines a slope of a change in temperature over the period based on the plurality of temperature values. For example, the controller 100 may determine the slope of change in temperature over the period based on the plurality of temperature values.

At 506, the method 500, in response to an absolute value of the slope being less than or equal to a threshold, initiates a first cooling function. For example, the controller 100 may, in response to the absolute value of the slope being less than or equal to the threshold, initiate the first cooling function.

At 508, the method 500, in response to the absolute value of the slope being greater than the threshold, initiates a second cooling function. For example, the controller 100 may, in response to the absolute value of the slope being greater than the threshold, initiate the second cooling function.

In some embodiments, a method for electrical component temperature control includes, in response to an ignition on signal indicating an ignition is in an on position, receiving a plurality of temperature values from a temperature sensor over a period, the temperature sensor being associated with at least one electrical component; determining a slope of a change in temperature over the period based on the plurality of temperature values; in response to an absolute value of the slope being less than or equal to a threshold, initiating a first cooling function; and, in response to the absolute value of the slope being greater than the threshold, initiating a second cooling function.

In some embodiments, the first cooling function is configured to cool the at least one electrical component based on a first cooling rate. In some embodiments, the second cooling function is configured to cool the at least one electrical component based on a second cooling rate. In some embodiments, the period includes a period that starts at the ignition on signal indicating that the ignition is on and ends at a predetermined time. In some embodiments, the period includes a period that starts at an ignition off signal indicating the ignition is off and ends a predetermined time after the ignition on signal indicates that the ignition is on. In some embodiments, the method also includes determining a time associated with the ignition off signal and a time associated with the ignition on signal, and estimating an ignition off period associated based on the time associated with the ignition off signal and the tie associated with the ignition on signal. In some embodiments, determining the slope of the change in temperature over the period based on the plurality of temperature values includes: determining a first temperature value associated with the at least one electrical component at the time associated with the ignition off signal; determining a second temperature value associated with the at least one electrical component at the time associated with the ignition on signal; determining a slope of change in temperature over the ignition off period based on the estimated ignition off period, the first temperature value, and the second temperature value; and determining the slope of the change in temperature over the period based on the plurality of temperature values and the slope of change in temperature over the ignition off period. In some embodiments, the at least one electrical component is associated with a steering system of a vehicle. In some embodiments, the steering system includes an electronic power steering system.

In some embodiments, a system for electrical component temperature control includes a processor, and a memory. The memory includes instructions that, when executed by the processor, cause the processor to: in response to an ignition on signal indicating an ignition is in an on position, receive a plurality of temperature values from a temperature sensor over a period, the temperature sensor being associated with at least one electrical component; determine a slope of a change in temperature over the period based on the plurality of temperature values; in response to an absolute value of the slope being less than or equal to a threshold, initiate a first cooling function; and, in response to the absolute value of the slope being greater than the threshold, initiate a second cooling function.

In some embodiments, the first cooling function is configured to cool the at least one electrical component based on a first cooling rate. In some embodiments, the second cooling function is configured to cool the at least one electrical component based on a second cooling rate. In some embodiments, the period includes a period that starts at the ignition on signal indicating that the ignition is on and ends at a predetermined time. In some embodiments, the period includes a period that starts at an ignition off signal indicating the ignition is off and ends a predetermined time after the ignition on signal indicates that the ignition is on. In some embodiments, the instructions further cause the processor to: determine a time associated with the ignition off signal and a time associated with the ignition on signal; and estimate an ignition off period associated based on the time associated with the ignition off signal and the tie associated with the ignition on signal. In some embodiments, the instructions further cause the processor to determine the slope of the change in temperature over the period based on the plurality of temperature values by: determining a first temperature value associated with the at least one electrical component at the time associated with the ignition off signal; determining a second temperature value associated with the at least one electrical component at the time associated with the ignition on signal; determining a slope of change in temperature over the ignition off period based on the estimated ignition off period, the first temperature value, and the second temperature value; and determining the slope of the change in temperature over the period based on the plurality of temperature values and the slope of change in temperature over the ignition off period. In some embodiments, the at least one electrical component is associated with a steering system of a vehicle. In some embodiments, the steering system includes an electronic power steering system.

In some embodiments, an apparatus for electrical component temperature control includes a controller configured to: in response to an ignition on signal indicating an ignition is in an on position, receive a plurality of temperature values from a temperature sensor over a period that starts at an ignition off signal indicating the ignition is off and ends a predetermined time after the ignition on signal indicates that the ignition is on, the temperature sensor being associated with at least one electrical component; determine a slope of a change in temperature over the period based on the plurality of temperature values; in response to an absolute value of the slope being less than or equal to a threshold, initiate a first cooling function configured to cool the at least one electrical component based on a first cooling rate; and, in response to the absolute value of the slope being greater than the threshold, initiate a second cooling function configured to cool the at least one electrical component based on a second cooling rate.

In some embodiments, the controller is further configured to: determine a time associated with the ignition off signal and a time associated with the ignition on signal; estimate an ignition off period associated based on the time associated with the ignition off signal and the tie associated with the ignition on signal; and determine the slope of the change in temperature over the period based on the plurality of temperature values by: determining a first temperature value associated with the at least one electrical component at the time associated with the ignition off signal; determining a second temperature value associated with the at least one electrical component at the time associated with the ignition on signal; determining a slope of change in temperature over the ignition off period based on the estimated ignition off period, the first temperature value, and the second temperature value; and determining the slope of the change in temperature over the period based on the plurality of temperature values and the slope of change in temperature over the ignition off period.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

The word “example” is used herein to mean serving as an example, instance, or illustration. Any aspect or design described herein as “example” is not necessarily to be construed as preferred or advantageous over other aspects or designs. Rather, use of the word “example” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an implementation” or “one implementation” throughout is not intended to mean the same embodiment or implementation unless described as such.

Implementations the systems, algorithms, methods, instructions, etc., described herein can be realized in hardware, software, or any combination thereof. The hardware can include, for example, computers, intellectual property (IP) cores, application-specific integrated circuits (ASICs), programmable logic arrays, optical processors, programmable logic controllers, microcode, microcontrollers, servers, microprocessors, digital signal processors, or any other suitable circuit. In the claims, the term “processor” should be understood as encompassing any of the foregoing hardware, either singly or in combination. The terms “signal” and “data” are used interchangeably.

As used herein, the term module can include a packaged functional hardware unit designed for use with other components, a set of instructions executable by a controller (e.g., a processor executing software or firmware), processing circuitry configured to perform a particular function, and a self-contained hardware or software component that interfaces with a larger system. For example, a module can include an application specific integrated circuit (ASIC), a Field Programmable Gate Array (FPGA), a circuit, digital logic circuit, an analog circuit, a combination of discrete circuits, gates, and other types of hardware or combination thereof. In other embodiments, a module can include memory that stores instructions executable by a controller to implement a feature of the module.

Further, in one aspect, for example, systems described herein can be implemented using a general-purpose computer or general-purpose processor with a computer program that, when executed, carries out any of the respective methods, algorithms, and/or instructions described herein. In addition, or alternatively, for example, a special purpose computer/processor can be utilized which can contain other hardware for carrying out any of the methods, algorithms, or instructions described herein.

Further, all or a portion of implementations of the present disclosure can take the form of a computer program product accessible from, for example, a computer-usable or computer-readable medium. A computer-usable or computer-readable medium can be any device that can, for example, tangibly contain, store, communicate, or transport the program for use by or in connection with any processor. The medium can be, for example, an electronic, magnetic, optical, electromagnetic, or a semiconductor device. Other suitable mediums are also available.

The above-described embodiments, implementations, and aspects have been described in order to allow easy understanding of the present disclosure and do not limit the present disclosure. On the contrary, the disclosure is intended to cover various modifications and equivalent arrangements included within the scope of the appended claims, which scope is to be accorded the broadest interpretation so as to encompass all such modifications and equivalent structure as is permitted under the law.

What is claimed is:

1. A method for electrical component temperature control, the method comprising:
in response to an ignition on signal indicating an ignition is in an on position, receiving a plurality of temperature values from a temperature sensor over a period, the temperature sensor being associated with at least one electrical component;
determining a slope of a change in temperature over the period based on the plurality of temperature values;
in response to an absolute value of the slope being less than or equal to a threshold, initiating a first cooling function; and
in response to the absolute value of the slope being greater than the threshold, initiating a second cooling function.

2. The method of claim 1, wherein the first cooling function is configured to cool the at least one electrical component based on a first cooling rate.

3. The method of claim 1, wherein the second cooling function is configured to cool the at least one electrical component based on a second cooling rate.

4. The method of claim 1, wherein the period includes a period that starts at the ignition on signal indicating that the ignition is on and ends at a predetermined time.

5. The method of claim 1, wherein the period includes a period that starts at an ignition off signal indicating the ignition is off and ends a predetermined time after the ignition on signal indicates that the ignition is on.

6. The method of claim 5, further comprising:
determining a time associated with the ignition off signal and a time associated with the ignition on signal; and
estimating an ignition off period associated based on the time associated with the ignition off signal and the tie associated with the ignition on signal.

7. The method of claim 6, wherein determining the slope of the change in temperature over the period based on the plurality of temperature values includes:
determining a first temperature value associated with the at least one electrical component at the time associated with the ignition off signal;
determining a second temperature value associated with the at least one electrical component at the time associated with the ignition on signal;
determining a slope of change in temperature over the ignition off period based on the estimated ignition off period, the first temperature value, and the second temperature value; and
determining the slope of the change in temperature over the period based on the plurality of temperature values and the slope of change in temperature over the ignition off period.

8. The method of claim 1, wherein the at least one electrical component is associated with a steering system of a vehicle.

9. The method of claim 8, wherein the steering system includes an electronic power steering system.

10. A system for electrical component temperature control, the system comprising:
a processor; and
a memory including instructions that, when executed by the processor, cause the processor to:
in response to an ignition on signal indicating an ignition is in an on position, receive a plurality of temperature values from a temperature sensor over a period, the temperature sensor being associated with at least one electrical component;
determine a slope of a change in temperature over the period based on the plurality of temperature values;
in response to an absolute value of the slope being less than or equal to a threshold, initiate a first cooling function; and
in response to the absolute value of the slope being greater than the threshold, initiate a second cooling function.

11. The system of claim 10, wherein the first cooling function is configured to cool the at least one electrical component based on a first cooling rate.

12. The system of claim 10, wherein the second cooling function is configured to cool the at least one electrical component based on a second cooling rate.

13. The system of claim 10, wherein the period includes a period that starts at the ignition on signal indicating that the ignition is on and ends at a predetermined time.

14. The system of claim 10, wherein the period includes a period that starts at an ignition off signal indicating the ignition is off and ends a predetermined time after the ignition on signal indicates that the ignition is on.

15. The system of claim 14, wherein the instructions further cause the processor to:
determine a time associated with the ignition off signal and a time associated with the ignition on signal; and
estimate an ignition off period associated based on the time associated with the ignition off signal and the tie associated with the ignition on signal.

16. The system of claim 15, wherein the instructions further cause the processor to determine the slope of the change in temperature over the period based on the plurality of temperature values by:
determining a first temperature value associated with the at least one electrical component at the time associated with the ignition off signal;
determining a second temperature value associated with the at least one electrical component at the time associated with the ignition on signal;
determining a slope of change in temperature over the ignition off period based on the estimated ignition off period, the first temperature value, and the second temperature value; and
determining the slope of the change in temperature over the period based on the plurality of temperature values and the slope of change in temperature over the ignition off period.

17. The system of claim 10, wherein the at least one electrical component is associated with a steering system of a vehicle.

18. The system of claim 17, wherein the steering system includes an electronic power steering system.

19. An apparatus for electrical component temperature control, the apparatus comprising:
a controller configured to:
in response to an ignition on signal indicating an ignition is in an on position, receive a plurality of temperature values from a temperature sensor over a period that starts at an ignition off signal indicating the ignition is off and ends a predetermined time after the ignition on signal indicates that the ignition is on, the temperature sensor being associated with at least one electrical component;
determine a slope of a change in temperature over the period based on the plurality of temperature values;
in response to an absolute value of the slope being less than or equal to a threshold, initiate a first cooling function configured to cool the at least one electrical component based on a first cooling rate; and
in response to the absolute value of the slope being greater than the threshold, initiate a second cooling function configured to cool the at least one electrical component based on a second cooling rate.

20. The apparatus of claim 19, wherein the controller is further configured to:
determine a time associated with the ignition off signal and a time associated with the ignition on signal;
estimate an ignition off period associated based on the time associated with the ignition off signal and the tie associated with the ignition on signal; and
determine the slope of the change in temperature over the period based on the plurality of temperature values by:
determining a first temperature value associated with the at least one electrical component at the time associated with the ignition off signal;
determining a second temperature value associated with the at least one electrical component at the time associated with the ignition on signal;
determining a slope of change in temperature over the ignition off period based on the estimated ignition off period, the first temperature value, and the second temperature value; and
determining the slope of the change in temperature over the period based on the plurality of temperature values and the slope of change in temperature over the ignition off period.
